(19) United States
(12) Patent Application Publication
(10) Pub. No.: US 2024/0105830 A1
(43) Pub. Date: Mar. 28, 2024

(54) TRANSISTOR STRUCTURE AND FORMING METHOD THEREOF

(71) Applicant: Hon Young Semiconductor Corporation, Hsinchu City (TW)

(72) Inventor: Yan-Ru CHEN, Hsinchu (TW)

(21) Appl. No.: 18/170,524

(22) Filed: Feb. 16, 2023

(30) Foreign Application Priority Data
Sep. 23, 2022 (TW) 111136238

(51) Int. Cl. H01L 29/78; H01L 29/06; H01L 29/10; H01L 29/40; H01L 29/423

(52) U.S. Cl. CPC H01L 29/7802; H01L 29/0619; H01L 29/1095; H01L 29/407; H01L 29/42376

(57) ABSTRACT

The present disclosure provides a transistor structure including a semiconductor stack, a gate structure, and a conductive element. The semiconductor stack includes a drift layer above a substrate, a first doping region in the drift layer, and a depletion region in the drift layer adjacent to the first doping region. The drift region has a first conductive type, and the first doping region has a second conductive type. The gate structure is positioned on the semiconductor stack and covers the depletion region. The conductive element including a metal layer is in the depletion region, in which a top surface of the metal layer directly contacts a bottom surface of the gate structure.

### CROSS-REFERENCE TO RELATED APPLICATION

This application claims priority to Taiwan Application Serial Number 111136238, filed Sep. 23, 2022, which is herein incorporated by reference in its entirety.

### BACKGROUND

### Field of Invention

The present disclosure relates to the transistor structure and the forming method thereof.

### Description of Related Art

With advances in semiconductor technology, there has been increasing demand for faster processing systems and higher performance. To meet these demands, the semiconductor industry continues to enhance the transistor current to improve the power conversion efficiency of devices, such as metal oxide semiconductor field effect transistor (MOSFET). However, as different conductive types of the dopants are doped in the transistor device, a depletion region with few charge carriers and high resistivity may be easily formed between the different doped regions. This may adversely impact the transistor device, such as increasing the total resistivity of the device. Therefore, this challenge needs to be overcome for improving the efficiency of the transistor device to keep up with the development of semiconductor field.

### SUMMARY

According to some embodiments of the present disclosure, a transistor structure includes a semiconductor stack, a gate structure, and a conductive element. The semiconductor stack includes a drift layer above a substrate, a first doping region in the drift layer, and a depletion region in the drift layer adjacent to the first doping region. The drift layer has a first conductive type, and the first doping region had a second conductive type. The gate structure covering the depletion region is on the semiconductor stack. The conductive element including a metal layer is in the depletion region, in which a top surface of the metal layer directly contacts a bottom surface of the gate structure.

In some embodiments, a smallest distance between the conductive element and the first doping region is in a range of 0.4 μm to 0.6 μm.

In some embodiments, the gate structure includes gate portions, in which a width of a gap between the gate portions in a first direction is smaller than a width of the top surface of the metal layer in the first direction.

In some embodiments, a depth of the conductive element from a top surface of the semiconductor stack is in a range of 1.6 μm to 2.4 μm.

In some embodiments, the top surface of the metal layer includes a first portion directly contacting the gate structure and a second portion not contacting the gate structure, in which the second portion is lower than the bottom surface of the gate structure.

In some embodiments, the conductive element further includes a doping layer surrounding the metal layer, in which the doping layer has the first conductive type and a doping concentration higher than a doping concentration of the drift layer.

In some embodiments, a thickness of the doping layer is in a range of 0.2 μm to 0.3 μm.

In some embodiments, the doping concentration of the doping layer is in a range of 1×10¹⁸ atoms/cm³ to 1×10²⁰ atoms/cm³.

In some embodiments, the transistor structure further includes a source contact above the semiconductor stack adjacent to the gate structure and a drain contact below the semiconductor stack, in which an entire projection of the conductive element onto the drain contact overlaps the drain contact.

In some embodiments, the transistor structure further includes a second doping region having the first conductive type in the first doping region, and a third doping region having the second conductive type in the first doping region and adjacent to second doping region, in which a doping concentration of the second doping region is higher than that of the drift layer, and a doping concentration of the third doping region is higher than that of the first doping region.

According to some embodiments of the present disclosure, a method of forming a transistor structure includes providing a semiconductor stack, where the semiconductor stack includes a drift layer having a first conductive type above a substrate, a first doping region having a second conductive type in the drift layer, and a depletion region in the drift layer adjacent to the first doping region. The method also includes forming a gate structure covering the depletion region above the semiconductor stack, performing a first etching process to form a trench in the depletion region of the semiconductor stack, and filling the trench with a metal layer to form a conductive element, where a top surface of the metal layer directly contacts a bottom surface of the gate structure.

In some embodiments, the first etching process is performed after forming the gate structure, where the first etching process etches the gate structure to form an opening above the trench, and a width of the opening is smaller than that of the trench.

In some embodiments, the method further includes performing a second etching process after filling the trench with the metal layer to etch a portion of the top surface of the metal layer to a position lower than the bottom surface of the gate structure.

In some embodiments, the gate structure is formed after performing the first etching process, where the bottom surface of the gate structure directly contacts entire of the top surface of the metal layer.

In some embodiments, the method further includes performing an ion implanting process on the drift layer before performing the first etching process to form a doping layer in the depletion region, and the first etching process is performed to form the trench in the doping layer of the depletion region.

In some embodiments, a depth of the doping layer from a top surface of the semiconductor stack is in a range of 1.6 μm to 2.4 μm.

In some embodiments, the method further includes performing an ion implanting process on the drift layer after performing the first etching process to form a doping layer along the trench, where a thickness of the doping layer is in a range of 0.2 μm to 0.3 μm.

In some embodiments, a smallest distance between the doping layer and the first doping region is in a range of 0.4 μm to 0.6 μm.

In some embodiments, performing the ion implanting process includes doping the drift layer by using a dopant with the first conductive type, where a doping concentration of the ion implanting process is in a range of 1×10¹⁸ atoms/cm³ to 1×10²⁰ atoms/cm³.

In some embodiments, the method further includes performing an annealing process with an annealing temperature between 1400° C. and 1800° C. after performing the ion implanting process.

According to the above-mentioned embodiments of the present disclosure, the transistor structure of the present disclosure includes the conductive element in the depletion region of the semiconductor stack, and the top surface of the metal layer in the conductive element directly contacts the bottom surface of the gate structure. Therefore, the resistivity of the conductive path through the depletion region may be reduced, which improves the performance of the transistor structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a flow diagram of a method of forming a transistor structure according to some embodiments of the present disclosure.

FIGS. 2A to 2F illustrate cross-sectional views of intermediate stages of the transistor structure in the manufacturing process according to some embodiments of the present disclosure.

FIG. 3 illustrates a flow diagram of a method of forming a transistor structure according to some other embodiments of the present disclosure.

FIGS. 4A to 4G illustrate cross-sectional views of intermediate stages of the transistor structure in the manufacturing process according to some embodiments of the present disclosure.

FIG. 5 illustrates a flow diagram of a method of forming a transistor structure according to some other embodiments of the present disclosure.

FIGS. 6A to 6E illustrate cross-sectional views of intermediate stages of the transistor structure in a manufacturing process according to some embodiments of the present disclosure.

### DETAILED DESCRIPTION

The following disclosure provides many different embodiments, or examples, for implementing different features of the provided subject matter. Specific examples of components, values, arrangements, etc., are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides a transistor structure and a forming method thereof. The transistor structure includes a semiconductor stack having a depletion region, a gate structure covering the depletion region, and a conductive element in the depletion region. The conductive element includes a metal layer which a top surface of the metal layer directly contacts a bottom surface of the gate structure. The conductive element reduces the resistivity in the depletion region so that the total resistivity of the conductive path in the semiconductor stack is reduced. Therefore, the conductive element may increase the current intensity of the transistor structure and improve the device performance.

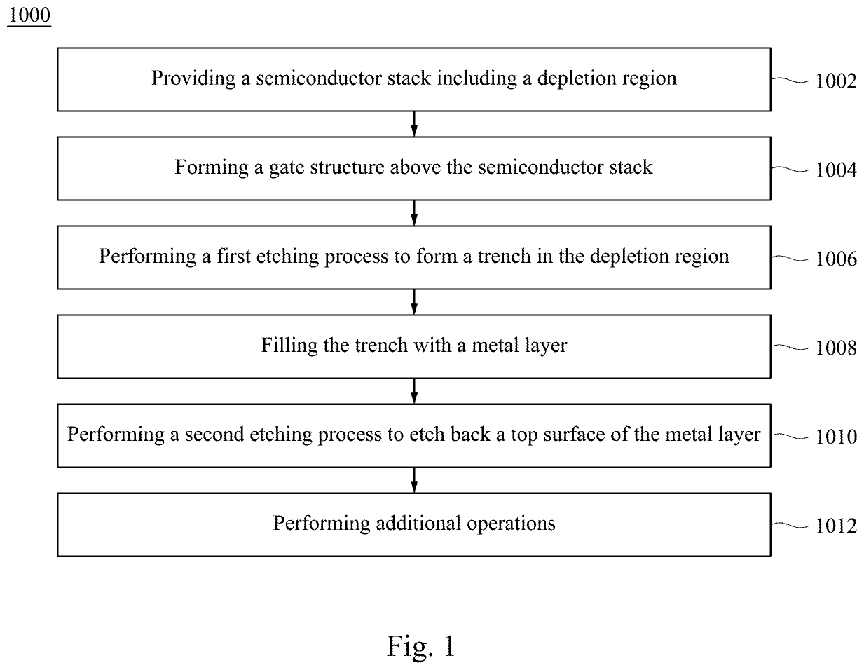

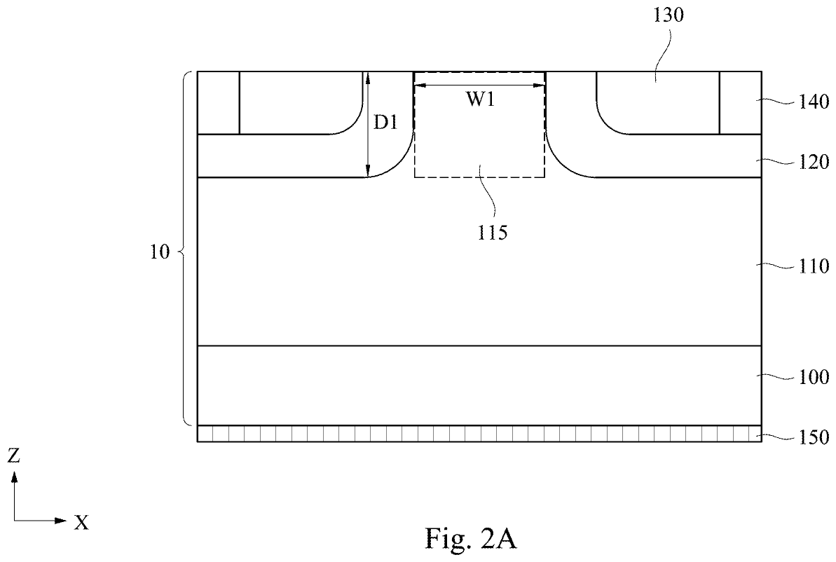

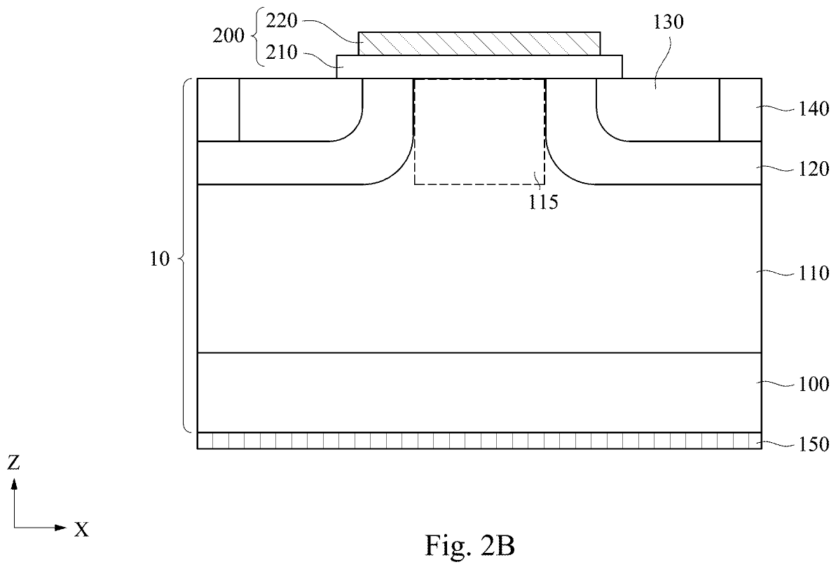

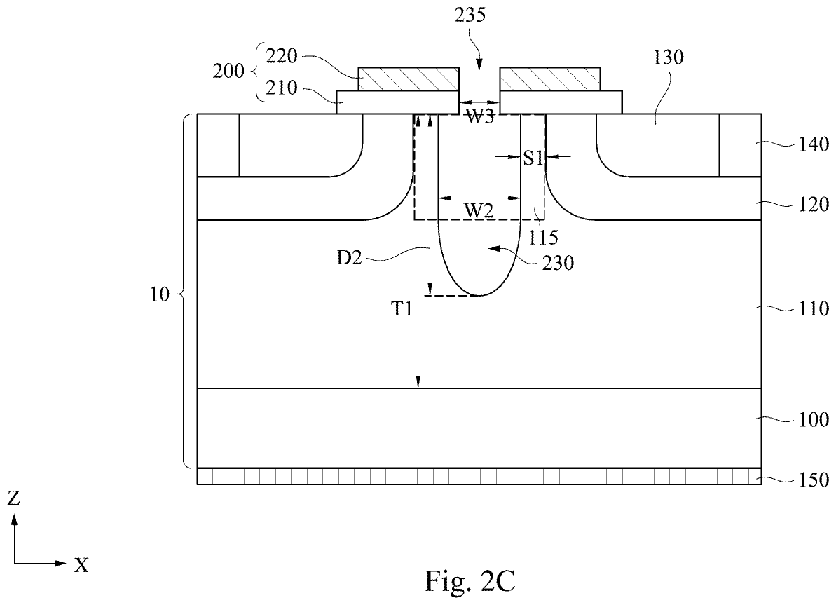

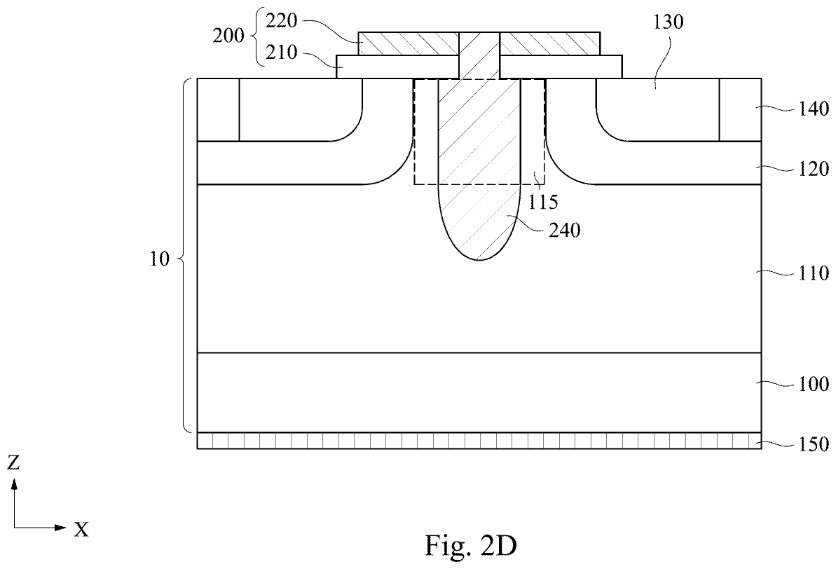

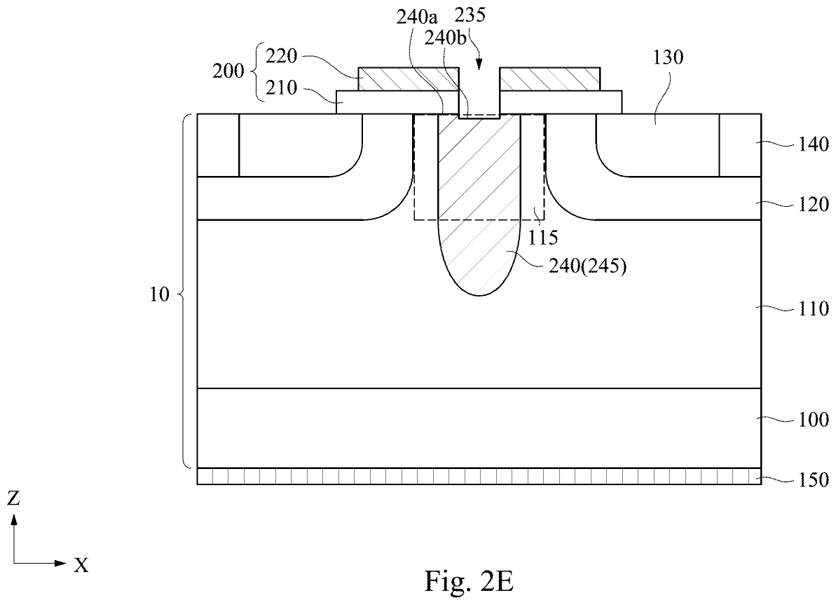

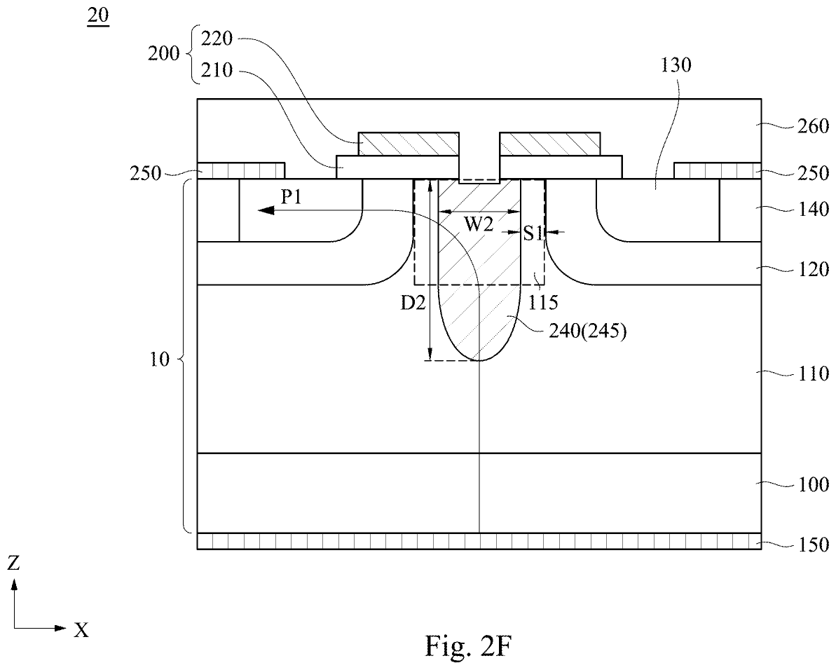

According to some embodiments of the present disclosure, FIG. 1 illustrates a flow diagram of a method 1000 of forming the transistor structure. FIGS. 2A to 2F illustrate cross-sectional views of the intermediate stages of a transistor structure 20 in the manufacturing process. The operations illustrated in FIG. 1 would be described below referring to the exemplary manufacturing process of the transistor structure 20. However, it would be apparent to those skilled in the art that the method illustrated in FIG. 1 may be applied to not only the transistor structure 20 but also other transistor structures including the depletion region in the scope of the present disclosure.

Unless otherwise illustrated, the order in which some or all operations in FIG. 1 and FIGS. 2A to 2F should not be construed to imply that these operations are necessarily order dependent. For example, some operations can be applied in orders different from the described embodiments, some operations can be applied simultaneously, some operations can be omitted and/or some operations can be repeated. In addition, additional operations can be provided before, during, and/or after the illustrated operations to form the transistor structure.

Referring to FIG. 1 and FIG. 2A, the method 1000 starts with step 1002, where a semiconductor stack 10 is provided. The semiconductor stack 10 includes a substrate 100, a drift layer 110, and a first doping region 120. Specifically, the substrate 100 may include a base material of the semiconductor stack 10. For example, the substrate 100 may include a silicon substrate, a silicon carbide substrate or the like. The drift layer 110 is above the substrate 100, where the drift layer 110 is formed by doping the base material of the semiconductor stack 10. For example, in the embodiment which the substrate 100 is a silicon substrate, the drift layer 110 may include a silicon material doped with nitrogen, phosphor or arsenide. The first doping region 120 is in the drift layer 110, where the first doping region 120 is doped with dopants having a conductive type different from those of in the drift layer 110. For example, the drift layer 110 may be doped with n-type dopants while the first doping region 120 is doped with p-type dopants. In some cases, the first doping region 120 doped with the p-type dopants may be referred as p-well. In some other embodiments, the drift layer 110 may be doped with p-type dopants while the first doping region 120 is doped with n-type dopants.

The drift layer 110 and the first doping region 120 have different conductive types so that a depletion region 115 is formed adjacent to the drift layer 110 in the first doping region 120. For example, as illustrated in FIG. 2A, the drift layer 110 with the n-type dopant and the first doping region 120 with the p-type dopant form a p-n junction between the drift layer 110 and the first doping region 120. The drift layer 110 near the p-n junction is affected by the charge carrier migration and forms the depletion region 115 having high resistivity. As the conductive path in the semiconductor stack 10 is formed from the drift layer 110 through the depletion region 115 to the first doping region 120, the high resistivity of the depletion region 115 reduces the current intensity and increases the total resistivity of the semiconductor stack 10. To overcome this issue, the structure for reducing the resistivity of the depletion region 115 and the forming method will be described below in detail.

In some embodiments, the depletion region 115 may be formed between the first doping regions 120, in which a width W1 of the depletion region 115 is similar to the distance between the first doping regions 120. For example, as shown in FIG. 2A, the width W1 of depletion region 115 in X-axis direction may be in a range of 1.6 μm to 2.4 μm. In some embodiments, a depth of the depletion region 115 may correspond to a depth D1 of the first doping region 120. For example, the depth D1 of the depletion region 115 in Z-axis direction may be in a range of 0.8 μm to 1.2 μm.

In some embodiments, the semiconductor stack 10 may further include a second doping region 130 in the first doping region 120 and a third doping region 140 adjacent to the second doping region 130 in the first doping region 120. The second doping region 130 and the third doping region 140 may be considered as the source region of the semiconductor stack 10, where the conductive path in the semiconductor stack 10 goes from the drift layer 110 to the second doping region 130 and the third doping region 140 through the depletion region 115 and the first doping region 120. The second doping region 130 and the third doping region 140 may have different conductive types. For example, the conductive type of the second doping region 130 may be the same as the drift layer 110 while a doping concentration of the second doping region 130 is higher than that of the drift layer 110. The conductive type of the third doping region 140 may be the same as the first doping region 120 while a doping concentration of the third doping region 140 is higher than that of the first doping region 120.

In some embodiments, a drain contact 150 may be provided below the semiconductor stack 10, where the conductive path in the semiconductor stack 10 goes from the drain contact 150 to the first doping region 120 through the drift layer 110 and the depletion region 115. The role of the drain contact 150 and the source contact formed later, such as the source contact 250 shown in FIG. 2F, may be swapped, which is not intended to limit the present disclosure.

Referring to FIG. 1 and FIG. 2B, the method 1000 continues to step 1004, where a gate structure 200 is formed above the semiconductor stack 10. The gate structure 200 is directly above the depletion region 115 so that the gate structure 200 covers the depletion region 115. Specifically, a gate dielectric layer 210 is first deposited above the depletion region 115 by, for example, chemical vapor deposition (CVD), physical vapor deposition (PVD) or other suitable deposition method. The gate dielectric layer 210 may include silicon oxide, aluminum oxide or other suitable high k value dielectric material. Then, a gate electrode layer 220 is deposited on the gate dielectric layer 210 to form the gate structure 200 including the gate dielectric layer 210 and the gate electrode layer 220. The gate electrode layer 220 may include aluminum metal or other suitable working function layer. As shown in FIG. 2B, the bottom surface of the gate dielectric layer 210 may cover the top surface of the semiconductor stack 10 so that the depletion region 115 is in the vertical projection area of the gate structure 200 in Z-axis direction.

Referring to FIG. 1 and FIG. 2C, the method 1000 continues to step 1006, where a first etching process is performed to form a trench 230 in the depletion region 115 of the semiconductor stack 10. Specifically, the first etching process is performed on the semiconductor stack 10 to form the trench 230 extending from the top surface of the semiconductor stack 10 into the depletion region 115. The trench 230 will be used for forming the conductive element that reduces the resistivity in the following processes. The first etching process may be, for example, a wet etching process, dry etching process or the like, and the first etching process may be anisotropic. In the embodiment shown in FIG. 2C, the trench 230 has vertical side walls and a curved bottom surface extending toward the drain contact 150, but it is not intended to limit the present disclosure. For example, in other embodiments, the trench 230 may have curved sidewalls or a flat bottom surface.

As shown in FIG. 2C, the first etching process is performed after forming the gate structure 200. As a result, the gate structure 200 above the depletion region 115 is also etched by the first etching process, thereby forming an opening 235 above the trench 230. In other words, the opening 235 extends through the gate structure 200 so that the trench 230 is exposed by the opening 235. The gate structure 200 becomes the gate portions separated by the opening 235. A width W3 of the opening 235 in X-axis direction is smaller than a width W2 of the trench 230 at the top surface of the semiconductor stack 10, leading to a portion of the gate structure 200 suspended above the trench 230. In other words, a portion of the bottom surface of the gate structure 200 is exposed above the trench 230. For example, a width W4 of the trench 230 may be in a range of 0.8 μm to 1.2 μm while a width W3 of the opening 235 may be in a range of 0.4 μm to 0.6 μm.

In some embodiments, a gap with appropriate width is between the trench 230 and the first doping region 120 so that a smallest distance S1 between the trench 230 and the first doping region 120 may be in a range of 0.4 μm to 0.6 μm. If the smallest distance S1 is smaller than 0.4 μm, the trench 230 may be too close to the first doping region 120, which easily leads to the leakage current between the first doping region 120 and the later formed conductive element. If the smallest distance S1 is larger than 0.6 μm, the unnecessarily large gap between the trench 230 and the first doping region 120 may undesirably increase the device volume.

In some embodiments, the trench 230 may extend from the top surface of the semiconductor stack 10 to an appropriate depth in Z-axis direction so that the trench 230 sufficiently occupies the depletion region 115. Referring to FIG. 2C, the trench 230 may further extend through the depletion region 115 to occupy sufficient volume in the semiconductor stack 10. For example, when the thickness T1 of the drift layer 110 is about 10 μm, a depth D2 of the trench 230 from the top surface of the semiconductor stack 10 may be in a range of 1.6 μm to 2.4 μm. If the depth D2 is smaller than 1.6 μm, the depth of the trench 230 may be too shallow to form the conductive element that can significantly reduce the resistivity of the depletion region 115. If the depth D2 is larger than 2.4 μm, the trench 230 may unnecessarily extend beyond the depletion region 115, which barely helps reducing the resistivity of the depletion region 115.

Referring to FIG. 1, FIG. 2C and FIG. 2D, the method 1000 continues to step 1008, where the trench 230 is filled with a metal layer 240. Specifically, a deposition process, such as chemical vapor deposition, atomic layer deposition (ALD) or other suitable deposition method, is performed in the trench 230 by using a metal material to fill the trench 230 and thus form the metal layer 240. As shown in FIGS. 2C and 2D, the opening 235 above the trench 230 may also be filled with the metal layer 240 so that the top surface of the metal layer 240 is coplanar with the top surface of the gate structure 200. It should be noted that as the width W3 of the opening 235 is smaller than the width W2 of the trench 230, a portion of the bottom surface of the gate structure 200 contacts the metal layer 240 after the trench 230 is filled with the metal layer 240.

In some embodiments, the metal layer 240 may include suitable metal material to provide high conductivity, such as aluminum, titanium, copper, alloys thereof or combinations thereof. In some embodiments, the metal layer 240 may be a single metal layer or a combination of multiple metal layers. In some embodiments, an adhesion layer (not shown) may be formed in the trench 230 before the formation of the metal layer 240 to improve the bonding between the metal layer 240 and the drift layer 110. For example, in the embodiments which the metal layer 240 includes titanium, a titanium nitride layer may be formed as an adhesion layer between the metal layer 240 and the drift layer 110.

Referring to FIG. 1 and FIG. 2E, the method 1000 continues to step 1010, where a second etching process is performed to etch back the metal layer 240. As a result, a portion of the top surface of the metal layer 240 is lower than the bottom surface of the gate structure 200. Specifically, the second etching process is performed on the metal layer 240 to etch the metal layer 240 between the gate portions of the gate structure 200. The etched metal layer 240 between the gate portions is lower than the bottom surface of the gate structure 200, thereby forming the gap between the gate portions with a width smaller than that of the top surface of the metal layer 240 in X-axis direction. In other words, the second etching process reproduces the opening 235 in FIG. 2C and further extends the bottom surface of the opening 235 until it is lower than the bottom surface of the gate structure 200. The second etching process may be, for example, a wet etching process, dry etching process or the like, and the second etching process may be anisotropic.

After the second etching process, the top surface of the metal layer 240 includes a first portion 240a directly contacting the gate structure 200 and a second portion 240b not contacting the gate structure 200. In other words, the first portion 240a of the top surface of the metal layer 240 is coplanar with the bottom surface of the gate dielectric layer 210, and the second portion 240b of the top surface of the metal layer 240 is lower than the bottom surface of the gate dielectric layer 210. Since the first portion 240a of the metal layer 240 is separated from the gate electrode layer 220 by the gate dielectric layer 210, and the second portion 240b of the metal layer 240 is lower than the bottom surface of the gate dielectric layer 210, the metal layer 240 is electrically isolated from the gate structure 200.

As a result, after the step 1010, the metal layer 240 forms the conductive element 245 in the depletion region 115. In the final structure of the formed transistor, the metal layer 240 is not connected to the drain contact 150 or the later formed source contact while the metal layer 240 is separated from the gate electrode layer 220 by the gate dielectric layer 210. Therefore, the metal layer 240 in the conductive element 245 has a floating potential. The low resistivity of the metal layer 240 helps to reduce the total resistivity of the semiconductor stack 10.

Specifically, the first portion 240a of the top surface of the metal layer 240 directly contacts the bottom surface of the gate structure 200 so that the vertical projection of the gate structure 200 onto the semiconductor stack 10 at least partially overlap with the metal layer 240. The overlapped gate structure 200 and metal layer 240 may provide the conductive path from the drift layer 110 to the first doping region 120, where the path passes through the metal layer 240 in the depletion region 115. The resistivity of the resulted conductive path is reduced, thereby increasing the current intensity of the semiconductor stack 10.

Referring to FIG. 1 and FIG. 2F, the method 1000 continues to step 1012, where additional operations are performed to form the transistor structure 20. For example, a source contact 250 and a dielectric layer 260 may be formed above the semiconductor stack 10. The source contact 250 is on the top surface of the semiconductor stack 10 and adjacent to the gate structure 200, in which the source contact 250 and the drain contact 150 are on opposite sides of the semiconductor stack 10. As shown in FIG. 2F, the entire vertical projection of the metal layer 240 onto the drain contact 150 may overlap the drain contact 150 so that the conductive path P1 from the drain contact 150 to the source contact 250 would pass through the drift layer 110, the metal layer 240 and the first doping region 120. The dielectric layer 260 covers the semiconductor stack 10, the gate structure 200 and the source contact 250 to protect these elements below the dielectric layer 260. The opening 235 shown in FIG. 2E may be filled with the dielectric layer 260, in which the dielectric layer 260 contacts the top surface of the metal layer 240.

As shown in FIG. 2F, the transistor structure 20 includes the conductive element 245 in the depletion region 115. The metal layer 240 of the conductive element 245 extends from the top surface of the semiconductor stack 10 into the depletion region 115 so that the top surface of the metal layer 240 (especially the first portion 240a in FIG. 2E) directly contacts the bottom surface of the gate structure 200. Since the conductive element 245 reduces the resistivity in the depletion region 115, the total resistivity on the conductive path P1 of the semiconductor stack 10 is correspondingly reduced. Therefore, the conductive element 245 increases the current intensity of the transistor structure 20 and improves its device performance.

In some embodiments, the smallest distance S1 between the conductive element 245 and the first doping region 120 in X-axis direction may be in a range of 0.4 μm to 0.6 μm. The smallest distance S1 in this range may prevent the conductive element 245 and the first doping region 120 from being too close to cause the leakage current between them. In addition, the smallest distance S1 in this range may provide the conductive element 245 with sufficient metal volume to significantly reduce the resistivity of the depletion region 115. In some embodiments, the conductive element 245 may have the depth D2 from the top surface of the semiconductor stack 10 in Y-axis direction and the width W2 in X-axis direction so that the conductive element 245 has sufficient metal volume to significantly reduce the resistivity of the depletion region 115.

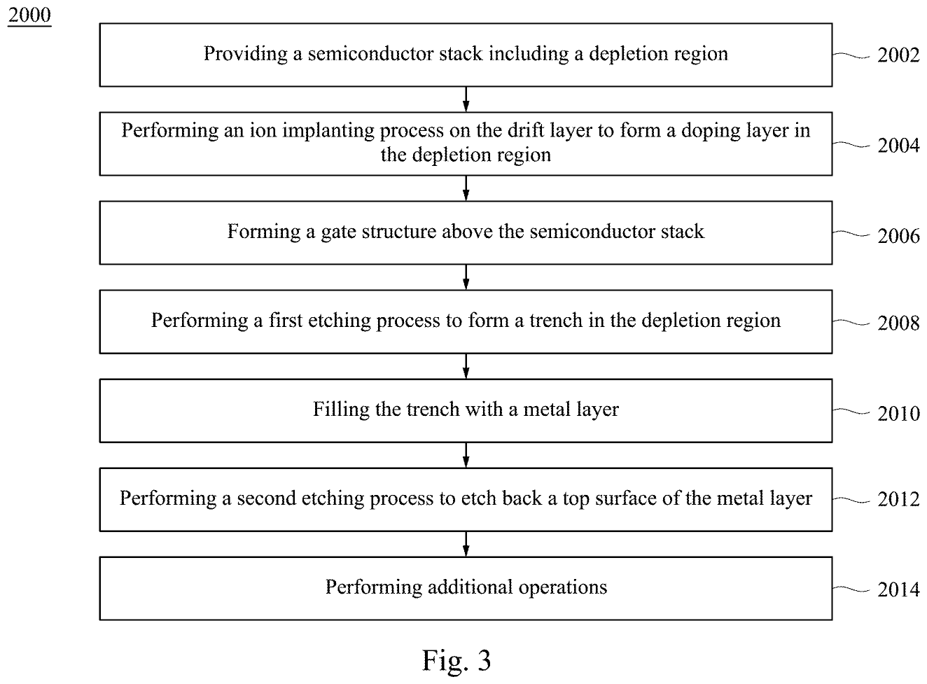

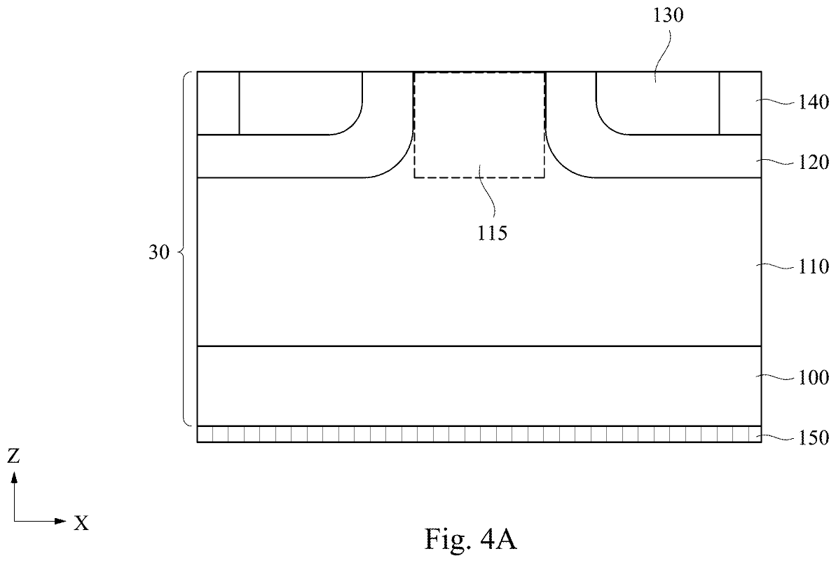

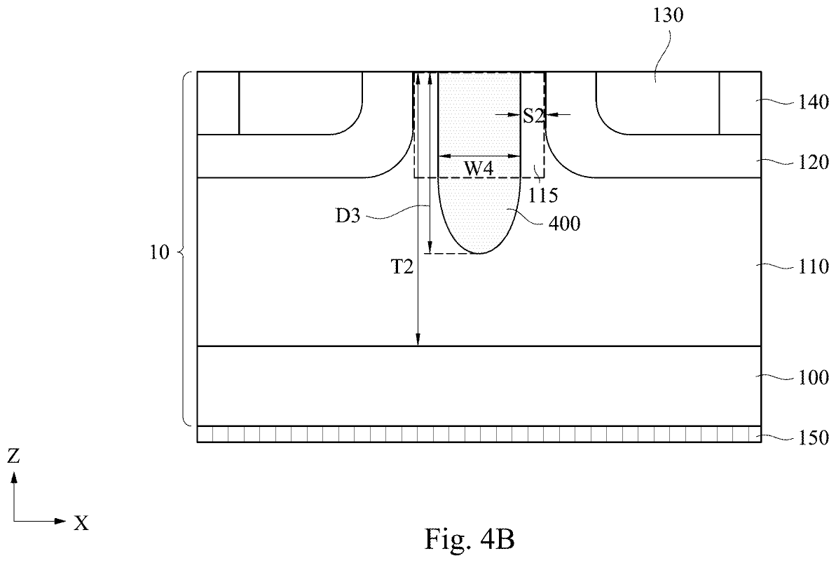

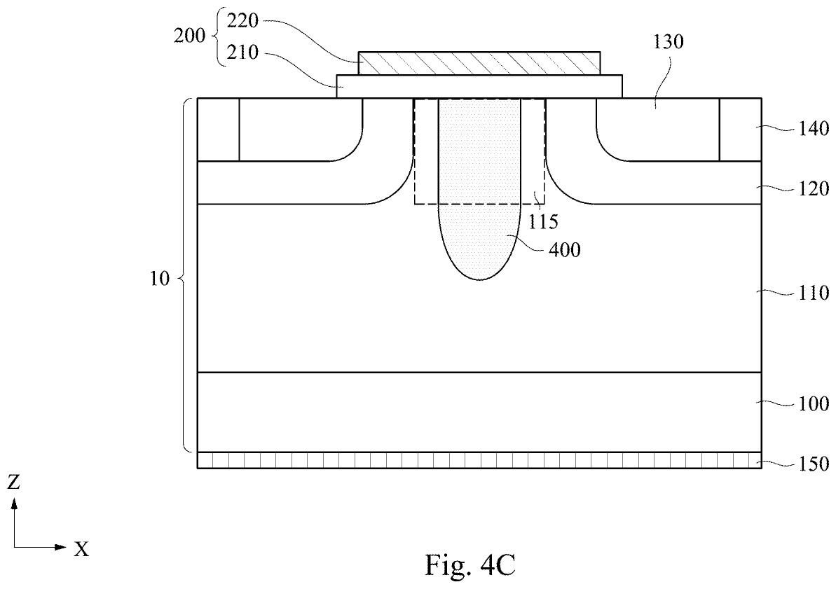

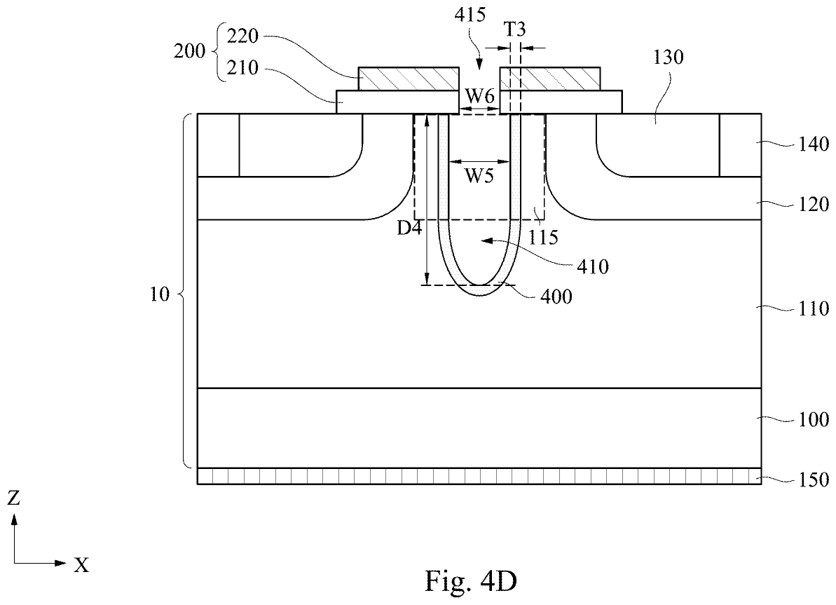

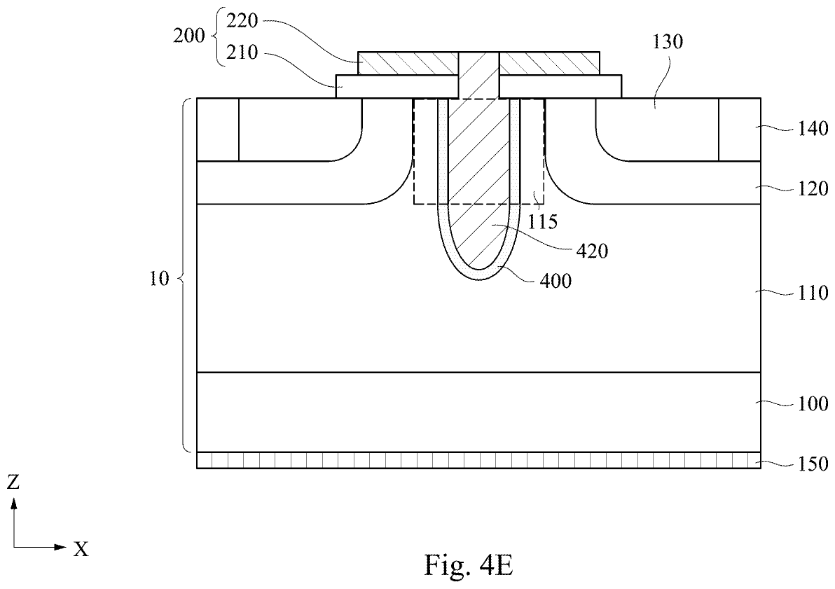

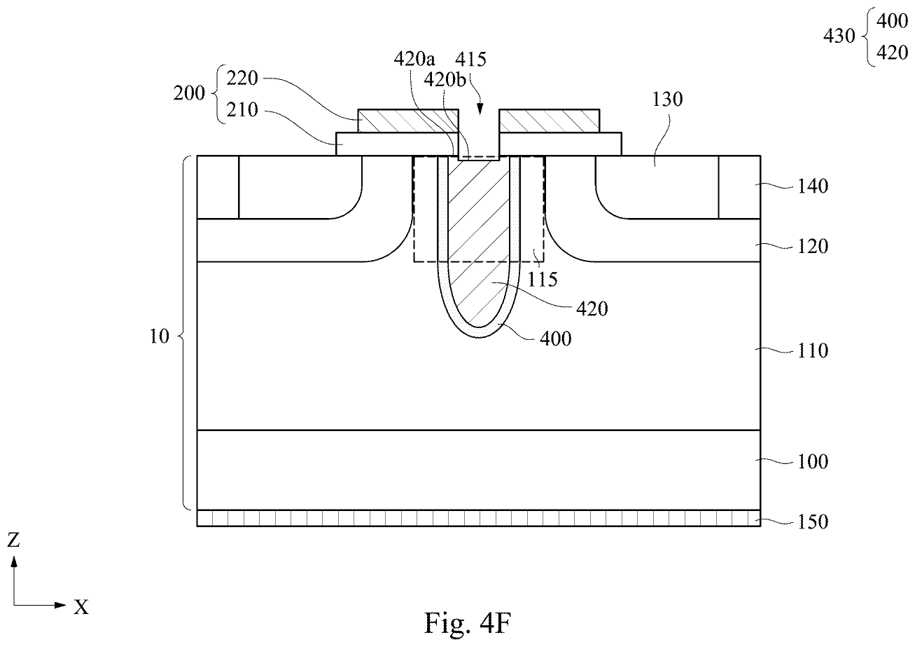

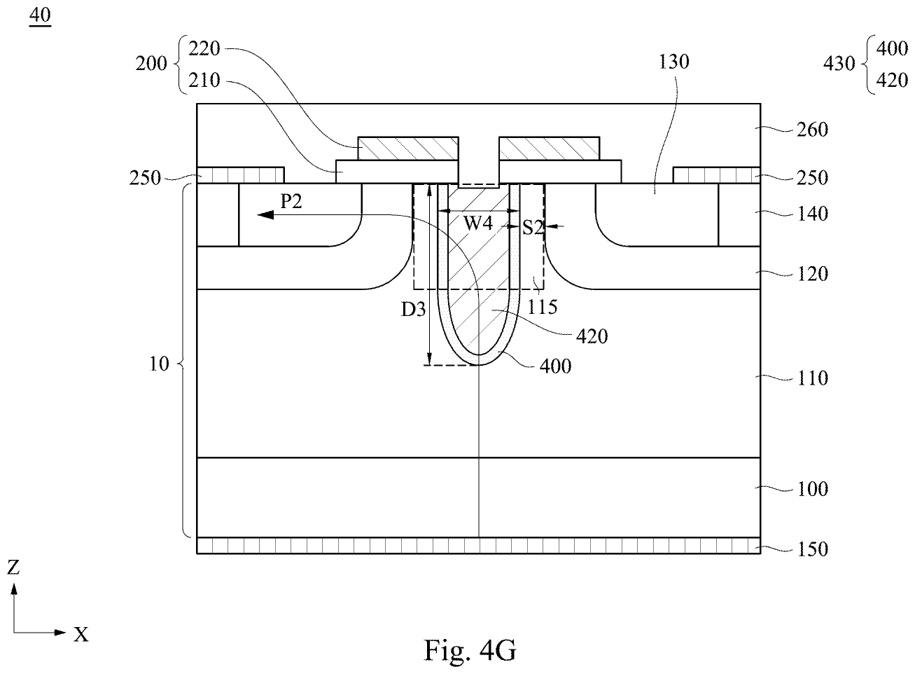

According to some other embodiments of the present disclosure, FIG. 3 illustrates a flow diagram of a method 2000 of forming the transistor structure. FIGS. 4A to 4G illustrate cross-sectional views of the intermediate stages of a transistor structure 40 in the manufacturing process. It should be noted that the transistor structure 40 has some features similar to those described referring to transistor structure 20. These similar features in FIGS. 4A to 4G would be labeled as the same reference numerals and/or letters as the transistor structure 20. The operations illustrated in FIG. 3 would be described below referring to the exemplary manufacturing process of the transistor structure 40. However, it would be apparent to those skilled in the art that the method illustrated in FIG. 3 may be applied to not only the transistor structure 40 but also other transistor structures including the depletion region in the scope of the present disclosure.

Unless otherwise illustrated, the order in which some or all operations in FIG. 3 and FIGS. 4A to 4G should not be construed to imply that these operations are necessarily order dependent. For example, some operations can be applied in orders different from the described embodiments, some operations can be applied simultaneously, some operations can be omitted and/or some operations can be repeated. In addition, additional operations can be provided before, during, and/or after the illustrated operations to form the transistor structure.

Referring to FIG. 3 and FIG. 4A, the method 2000 starts with step 2002, where a semiconductor stack 10 is provided. The semiconductor stack 10 includes a substrate 100, a drift layer 110, a first doping region 120 and a depletion region 115 adjacent to the first doping region 120. The step shown in FIG. 4A is similar to FIG. 2A, and the semiconductor stack 10 in FIG. 4A is similar to that of FIG. 2A, so other details are not described herein for simplicity.

Referring to FIG. 3 and FIG. 4B, the method 2000 continues to step 2004, where an ion implanting process is performed on the drift layer 110 to form a doping layer 400 in the depletion region 115. Specifically, a photoresist or a mask (not shown) is formed on the semiconductor stack 10 to expose the depletion region 115 while the photoresist or mask covers the other portion of the semiconductor stack 10. Then, the ions are implanted in the drift layer 110 of the depletion region 115 to form the doping layer 400 extending form the top surface of the semiconductor stack 10 into the depletion region 115. The doping layer 400 would be used to form the conductive element in the following processes for reducing the resistivity. In the embodiment shown in FIG. 4B, the doping layer 400 has vertical side walls and a curved bottom surface extending toward the drain contact 150, but it is not intended to limit the present disclosure. For example, in other embodiments, the doping layer 400 may have curved sidewalls or a flat bottom surface.

In some embodiments, a gap with appropriate width is between the doping layer 400 and the first doping region 120 so that a smallest distance S2 between the doping layer 400 and the first doping region 120 may be in a range of 0.4 μm to 0.6 μm. If the smallest distance S2 is smaller than 0.4 μm, the doping layer 400 may be too close to the first doping region 120, which easily leads to the leakage current between the first doping region 120 and the later formed conductive element. If the smallest distance S2 is larger than 0.6 μm, the unnecessarily large gap between the doping layer 400 and the first doping region 120 may undesirably increase the device volume.

In some embodiments, the doping layer 400 may extend from the top surface of the semiconductor stack 10 to an appropriate depth in Z-axis direction and have a large enough width in X-axis direction so that the doping layer 400 sufficiently occupies the depletion region 115. Referring to FIG. 4B, the doping layer 400 may further extend through the depletion region 115 to occupy sufficient volume in the semiconductor stack 10. For example, when the thickness T2 of the drift layer 110 is about 10 μm, a depth D3 of the doping layer 400 from the top surface of the semiconductor stack 10 may be in a range of 1.6 μm to 2.4 μm. A width W4 of the doping layer 400 at the top surface of the semiconductor stack 10 may be in a range of 0.8 μm to 1.2 μm.

In some embodiments, the ion implanting process may be performed by doping the depletion region 115 with suitable dopants which have the same conductive type as the drift layer 110. For example, in the embodiments which the drift layer 110 is doped with n-type dopants, the depletion region 115 may be doped with nitrogen, phosphor, arsenide or similar n-type dopants in the ion implanting process to form the doping layer 400. In some embodiments, a doping concentration of the doping layer 400 formed by the ion implanting process may be higher than that of the drift layer 110. For example, the doping concentration of the ion implanting process may be in a range of 1×10¹⁸ atoms/cm³ to 1×10²⁰ atoms/cm³. In some embodiments, an appropriate annealing process may be performed after the ion implanting process, such as the annealing process with an annealing temperature between 1400° C. and 1800° C.

Referring to FIG. 3 and FIG. 4C, the method 2000 continues to step 2006, where a gate structure 200 is formed above the semiconductor stack 10. The gate structure 200 is directly above the depletion region 115 so that the gate structure 200 covers the depletion region 115 and the doping layer 400 in the depletion region 115. The step shown in FIG. 4C is similar to FIG. 2B, and the gate structure 200 in FIG. 4C is similar to that of FIG. 2B, so other details are not described herein for simplicity.

Referring to FIG. 3 and FIG. 4D, the method 2000 continues to step 2008, where a first etching process is performed to form a trench 410 in the depletion region 115 of the semiconductor stack 10. Specifically, the first etching process is performed on the semiconductor stack 10 to form the trench 410 extending from the top surface of the semiconductor stack 10 into the depletion region 115. The trench 410 will be used for forming the conductive element in the following processes to reduce the resistivity. The first etching process may be, for example, a wet etching process, dry etching process or the like, and the first etching process may be anisotropic.

More specifically, the trench 410 is formed in the doping layer 400 in which the remained doping layer 400 has an uniform thickness between the drift layer 110 and the trench 410. In some embodiments, a depth D4 of the trench 410 from the top surface of the semiconductor stack 10 may be in a range of 1.4 μm to 2.1 μm, a width W5 of the trench 410 at the top surface of the semiconductor stack 10 may be in a range of 0.4 μm to 0.6 μm, and a thickness T3 of the remained doping layer 400 may be in a range of 0.2 μm to 0.3 μm. If the thickness T3 is smaller than 0.2 μm, it may become difficult for the thin doping layer 400 to have a uniform thickness. If the thickness T3 is larger than 0.3 μm, the trench 410 may be not large enough to form the metal layer in the following processes which significantly reduces the resistivity of the depletion region 115.

As shown in FIG. 4D, the first etching process is performed after forming the gate structure 200. As a result, the gate structure 200 above the depletion region 115 is also etched by the first etching process, thereby forming an opening 415 above the trench 410. The gate structure 200 becomes the gate portions separated by the opening 415 so that the trench 410 is exposed by the opening 415. A width W6 of the opening 415 in X-axis direction is smaller than a width W5 of the trench 410 at the top surface of the semiconductor stack 10, leading to a portion of the gate structure 200 suspended above the trench 410. In other words, a portion of the bottom surface of the gate structure 200 is exposed above the trench 410. For example, a width W5 of the trench 410 may be in a range of 0.4 μm to 0.6 μm while a width W6 of the opening 415 may be in a range of 0.2 μm to 0.3 μm.

Referring to FIG. 3, FIG. 4D and FIG. 4E, the method 2000 continues to step 2010, where the trench 410 is filled with a metal layer 420. As the width W6 of the opening 415 is smaller than the width W5 of the trench 410, a portion of the bottom surface of the gate structure 200 contacts the metal layer 420 after the trench 410 is filled with the metal layer 420. The step shown in FIG. 4E is similar to FIG. 2D, so other details are not described herein for simplicity.

Referring to FIG. 3 and FIG. 4F, the method 2000 continues to step 2012, where a second etching process is performed to etch back the metal layer 420. As a result, a portion of the top surface of the metal layer 420 is lower than the bottom surface of the gate structure 200. After the second etching process, the top surface of the metal layer 420 includes a first portion 420a directly contacting the gate structure 200 and a second portion 420b not contacting the gate structure 200. Since the first portion 420a of the metal layer 420 is separated from the gate electrode layer 220 by the gate dielectric layer 210, and the second portion 420b of the metal layer 420 is lower than the bottom surface of the gate dielectric layer 210, the metal layer 420 is electrically isolated from the gate structure 200. The step shown in FIG. 4F is similar to FIG. 2E, so other details are not described herein for simplicity.

As a result, after the step 2012, the conductive element 430 is formed in the depletion region 115, in which the conductive element 430 includes the metal layer 420 and the doping layer 400 surrounding the metal layer 420. The first portion 420a of the top surface of the metal layer 420 directly contacts the bottom surface of the gate structure 200 so that the vertical projection of the gate structure 200 onto the semiconductor stack 10 at least partially overlap with the metal layer 420. This may provide the conductive path in the semiconductor stack 10 that passes through the metal layer 420 in the depletion region 115, leading to the reduced total resistivity of the conductive path. The doping layer 400 around the metal layer 420 may further reduce the resistivity of the depletion region 115, thereby increasing the current intensity of the semiconductor stack 10.

Referring to FIG. 3 and FIG. 4G, the method 2000 continues to step 2014, where additional operations are performed to form the transistor structure 40, such as the formation of the source contact 250 and the dielectric layer 260. The step shown in FIG. 4G is similar to FIG. 2F, so other details are not described herein for simplicity.

As shown in FIG. 4G, the transistor structure 40 includes the conductive element 430 in the depletion region 115. The metal layer 420 of the conductive element 430 extends from the top surface of the semiconductor stack 10 into the depletion region 115 so that the top surface of the metal layer 420 (especially the first portion 420a in FIG. 4F) directly contacts the bottom surface of the gate structure 200. Since the conductive element 430 reduces the resistivity in the depletion region 115, the total resistivity on the conductive path P2 of the semiconductor stack 10 is correspondingly reduced. Therefore, the conductive element 430 increases the current intensity of the transistor structure 40 and improves its device performance.

In some embodiments, the smallest distance S2 between the conductive element 430 and the first doping region 120 in X-axis direction may be in a range of 0.4 μm to 0.6 μm. The smallest distance S2 in this range may prevent the conductive element 430 and the first doping region 120 from being too close to cause the leakage current between them. In addition, the smallest distance S2 in this range may provide the conductive element 430 with sufficient metal volume to significantly reduce the resistivity of the depletion region 115. In some embodiments, the conductive element 430 may have the depth D3 from the top surface of the semiconductor stack 10 in Y-axis direction and the width W4 in X-axis direction so that the conductive element 430 has sufficient metal volume to significantly reduce the resistivity of the depletion region 115.

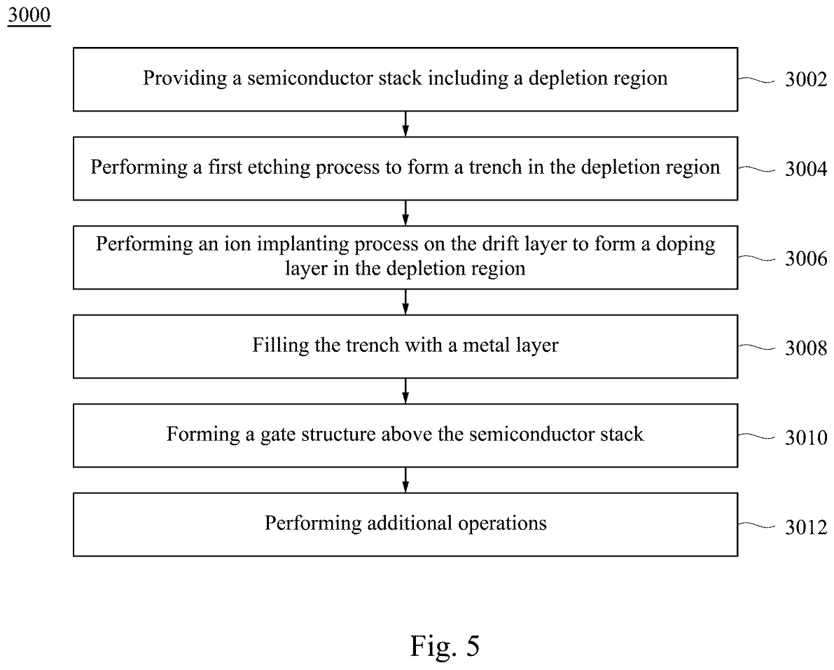

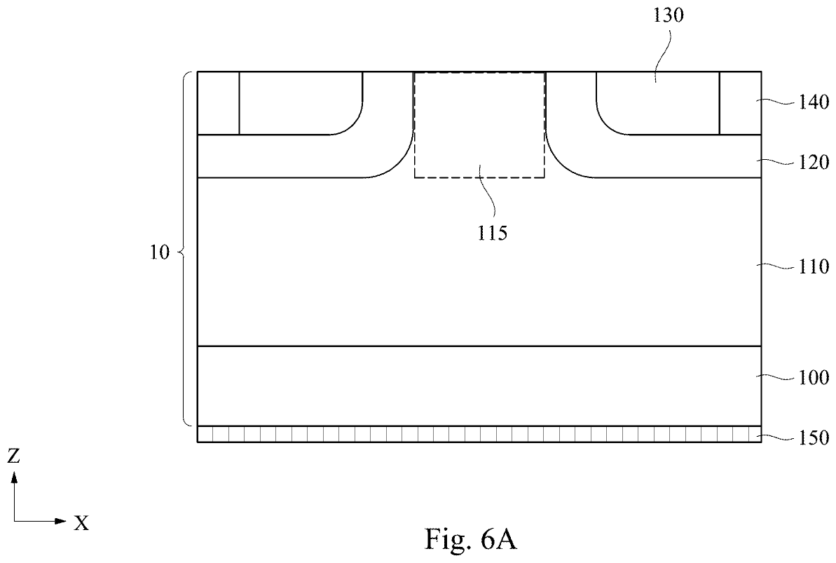

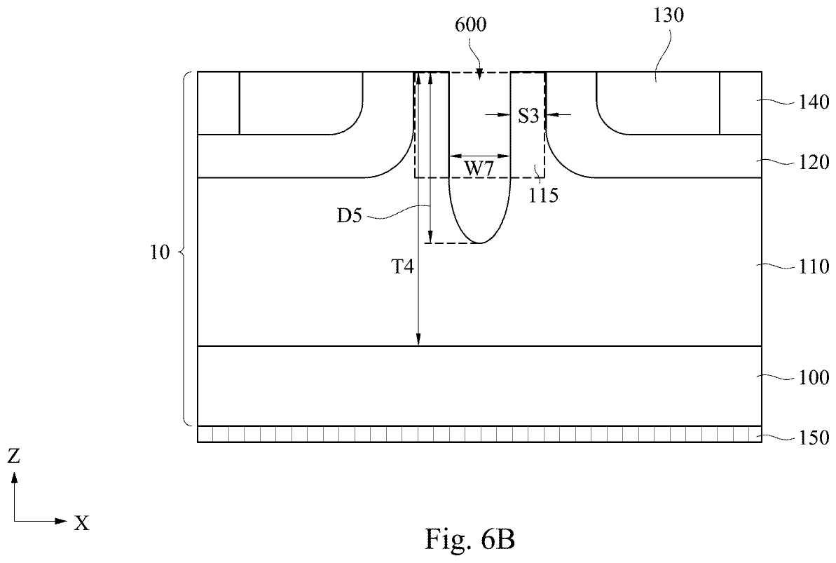

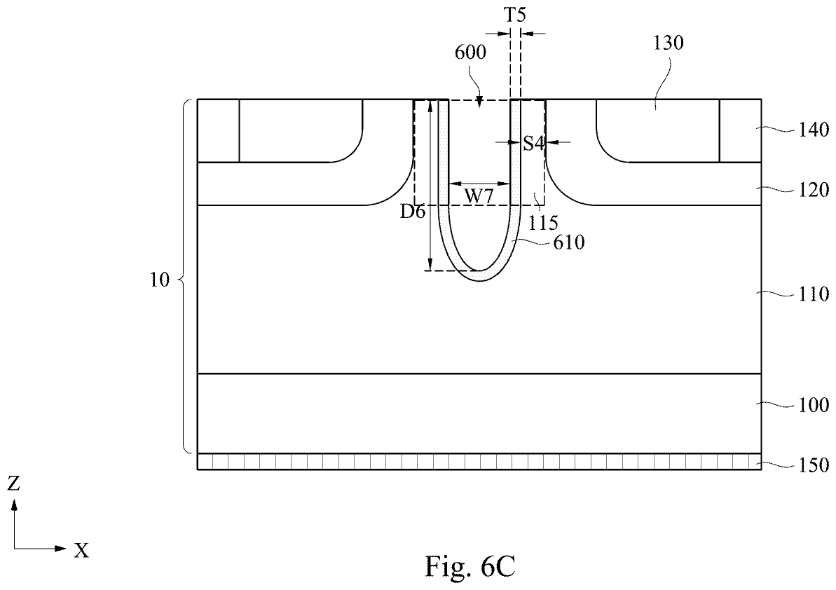

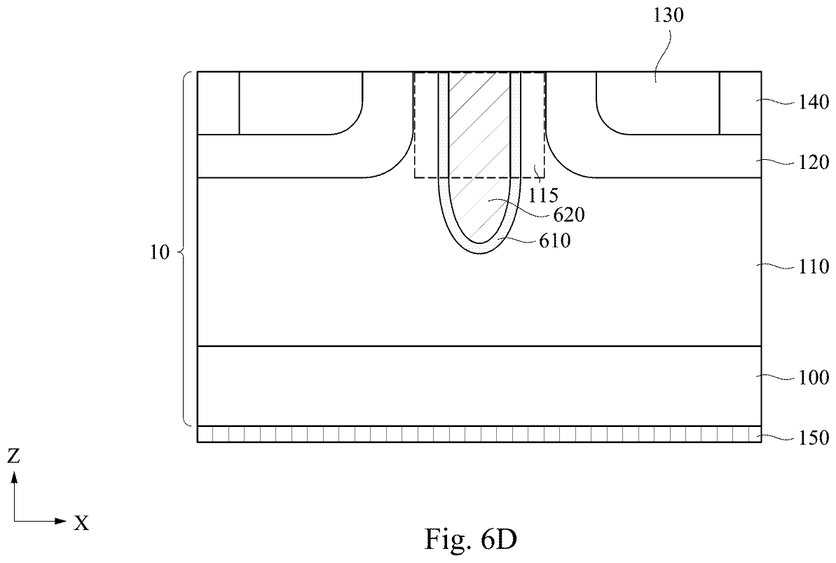

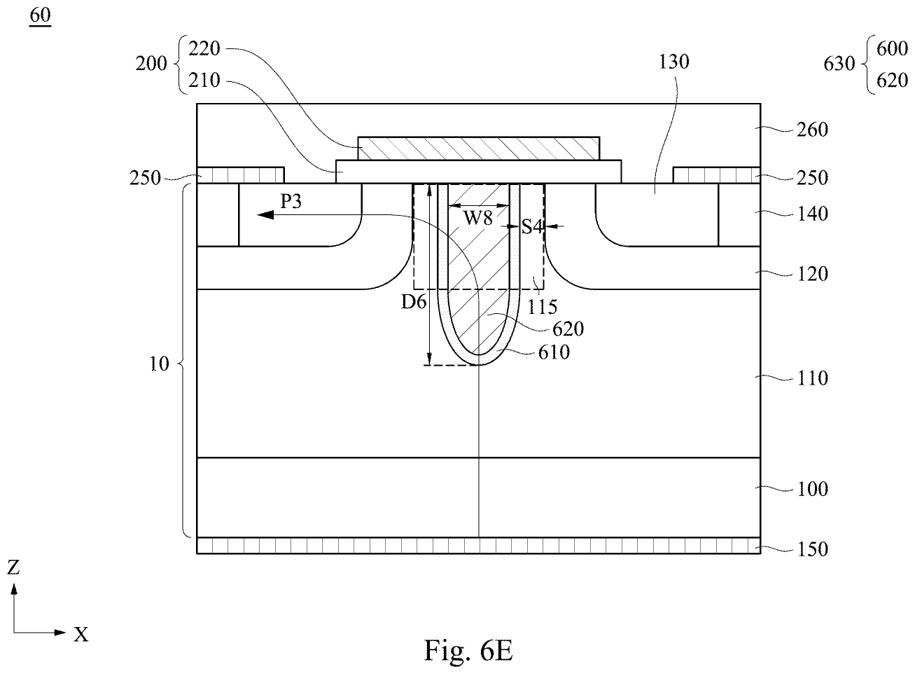

According to some other embodiments of the present disclosure, FIG. 5 illustrates a flow diagram of a method 3000 of forming the transistor structure. FIGS. 6A to 6E illustrate cross-sectional views of the intermediate stages of a transistor structure 60 in the manufacturing process. It should be noted that the transistor structure 60 has some features similar to those described referring to transistor structure 20. These similar features in FIGS. 6A to 6E would be labeled as the same reference numerals and/or letters as the transistor structure 20. The operations illustrated in FIG. 5 would be described below referring to the exemplary manufacturing process of the transistor structure 60. However, it would be apparent to those skilled in the art that the method illustrated in FIG. 5 may be applied to not only the transistor structure 60 but also other transistor structures including the depletion region in the scope of the present disclosure.

Unless otherwise illustrated, the order in which some or all operations in FIG. 5 and FIGS. 6A to 6E should not be construed to imply that these operations are necessarily order dependent. For example, some operations can be applied in orders different from the described embodiments, some operations can be applied simultaneously, some operations can be omitted and/or some operations can be repeated. In addition, additional operations can be provided before, during, and/or after the illustrated operations to form the transistor structure.

Referring to FIG. 5 and FIG. 6A, the method 3000 starts with step 3002, where a semiconductor stack 10 is provided. The semiconductor stack 10 includes a substrate 100, a drift layer 110, a first doping region 120 and a depletion region 115 adjacent to the first doping region 120. The step shown in FIG. 6A is similar to FIG. 2A, and the semiconductor stack 10 in FIG. 6A is similar to that of FIG. 2A, so other details are not described herein for simplicity.

Referring to FIG. 5 and FIG. 6B, the method 3000 continues to step 3004, where a first etching process is performed to form a trench 600 in the depletion region 115 of the semiconductor stack 10. Specifically, the first etching process is performed on the semiconductor stack 10 to form the trench 600 extending from the top surface of the semiconductor stack 10 into the depletion region 115. The trench 600 will be used for forming the conductive element in the following processes to reduce the resistivity. The first etching process may be, for example, a wet etching process, dry etching process or the like, and the first etching process may be anisotropic. In the embodiment shown in FIG. 6B, the trench 600 has vertical side walls and a curved bottom surface extending toward the drain contact 150, but it is not intended to limit the present disclosure. For example, in other embodiments, the trench 600 may have curved sidewalls or a flat bottom surface.

In some embodiments, a gap with appropriate width is between the trench 600 and the first doping region 120 so that a smallest distance S3 between the trench 600 and the first doping region 120 may be in a range of 0.6 μm to 0.9 μm. If the smallest distance S3 is smaller than 0.6 μm, the later formed doping layer (for example, the doping layer 610 in FIG. 6C) between the trench 600 and the first doping region 120 may be too close to the first doping region 120, which easily leads to the leakage current between the first doping region 120 and the doping layer. If the smallest distance S3 is larger than 0.9 μm, the unnecessarily large gap between the trench 600 and the first doping region 120 may undesirably increase the device volume.

In some embodiments, the trench 600 may extend from the top surface of the semiconductor stack 10 to an appropriate depth in Z-axis direction and have a large enough width in X-axis direction so that the trench 600 sufficiently occupies the depletion region 115. Referring to FIG. 6B, the trench 600 may further extend through the depletion region 115 to occupy sufficient volume in the semiconductor stack 10. For example, when the thickness T4 of the drift layer 110 is about 10 μm, a depth D5 of the trench 600 from the top surface of the semiconductor stack 10 may be in a range of 1.4 μm to 2.1 μm. A width W7 of the trench 600 at the top surface of the semiconductor stack 10 may be in a range of 0.4 μm to 0.6 μm.

Referring to FIG. 5 and FIG. 6C, the method 3000 continues to step 3006, where an ion implanting process is performed on the drift layer 110 to form a doping layer 610 along the trench 600 in the depletion region 115. Specifically, a photoresist or a mask (not shown) is formed on the semiconductor stack 10 to expose the trench 600 while the photoresist or mask covers the other portion of the semiconductor stack 10. Then, the ions are implanted in the trench 600 to form the doping layer 610 extending from the surface of the trench 600 into the drift layer 110. The doping layer 610 would be used to form the conductive element in the following processes for reducing the resistivity. The ion implanting process performed in the trench 600 may also repair the surface defects of the trench 600 to reduce the resistivity between the doping layer 610 and the later formed metal layer.

In some embodiments, the doping layer 610 may extend from the surface of the trench 600 to an appropriate depth into the drift layer 110. For example, a thickness T5 of the doping layer 610 may be in a range of 0.2 μm to 0.3 μm, leading to a depth D6 of the doping layer 610 in a range of 1.6 μm to 2.4 μm from the top surface of the semiconductor stack 10 and a smallest distance S4 in a range of 0.4 μm to 0.6 μm between the doping layer 610 and the first doping region 120. If the thickness T5 is smaller than 0.2 μm, it may become difficult for the thin doping layer 610 to have a uniform thickness. If the thickness T5 is larger than 0.3 μm, the doping layer 610 may be too close to the first doping region 120, which easily leads to the leakage current between the first doping region 120 and the doping layer 610.

In some embodiments, the ion implanting process may be performed by doping the depletion region 115 with suitable dopants which have the same conductive type as the drift layer 110. For example, in the embodiments which the drift layer 110 is doped with n-type dopants, the depletion region 115 may be doped with nitrogen, phosphor, arsenide or similar n-type dopants in the ion implanting process to form the doping layer 610. In some embodiments, a doping concentration of the doping layer 610 formed by the ion implanting process may be higher than that of the drift layer 110. For example, the doping concentration of the ion implanting process may be in a range of 1×10¹⁸ atoms/cm³ to 1×10²⁰ atoms/cm³. In some embodiments, an appropriate annealing process may be performed after the ion implanting process, such as the annealing process with an annealing temperature between 1400° C. and 1800° C.

Referring to FIG. 5, FIG. 6C and FIG. 6D, the method 3000 continues to step 3008, where the trench 600 is filled with a metal layer 620. Specifically, a deposition process is performed in the trench 600 by using a metal material to fill the trench 600 and thus form the metal layer 620. After the deposition process, the top surface of the metal layer 620 is coplanar with the top surface of the semiconductor stack 10. The step shown in FIG. 6D is similar to FIG. 2D, so other details are not described herein for simplicity.

Referring to FIG. 5 and FIG. 6E, the method 3000 continues to step 3010, where a gate structure 200 is formed above the semiconductor stack 10. The gate structure 200 is directly above the depletion region 115 so that the gate structure 200 covers the depletion region 115 as well as the doping layer 610 and the metal layer 620 in the depletion region 115. Since the top surface of the metal layer 620 is coplanar with the top surface of the semiconductor stack 10, the bottom surface of the gate structure 200 directly contacts the entire top surface of the metal layer 620. In such cases, the metal layer 620 is electrically isolated from the gate electrode layer 220 by the gate dielectric layer 210, so an additional etching process for etching back the metal layer 620 is unnecessary. In addition, the method 3000 may further continue to step 3012, where additional operations are performed to form the transistor structure 60, such as the formation of the source contact 250 and the dielectric layer 260. The step shown in FIG. 6E is similar to FIGS. 2B and 2F, so other details are not described herein for simplicity.

As a result, after the step 3012, the conductive element 630 is formed in the depletion region 115. The conductive element 630 includes the metal layer 620 and the doping layer 610 surrounding the metal layer 620. The top surface of the metal layer 620 directly contacts the bottom surface of the gate structure 200 so that the vertical projection of the gate structure 200 onto the semiconductor stack 10 at least partially overlap with the metal layer 620. This may provide the conductive path P3 in the semiconductor stack 10 that passes through the metal layer 620 in the depletion region 115, leading to the reduced total resistivity of the conductive path P3. The doping layer 610 around the metal layer 620 may further reduce the resistivity of the depletion region 115, thereby increasing the current intensity of the semiconductor stack 10. Therefore, the conductive element 630 reduces the total resistivity of the semiconductor stack 10, increases the current intensity of the transistor structure 60 and improves its device performance.

In some embodiments, the smallest distance S4 between the conductive element 630 and the first doping region 120 in X-axis direction may be in a range of 0.4 μm to 0.6 μm. The smallest distance S4 in this range may prevent the conductive element 630 and the first doping region 120 from being too close to cause the leakage current between them. In addition, the smallest distance S4 in this range may provide the conductive element 630 with sufficient metal volume to significantly reduce the resistivity of the depletion region 115. In some embodiments, the conductive element 630 may have the depth D6 from the top surface of the semiconductor stack 10 in Y-axis direction and the width W8 in X-axis direction in a range of 0.8 μm to 1.2 μm so that the conductive element 630 has sufficient metal volume to significantly reduce the resistivity of the depletion region 115.

According to the above-mentioned embodiments of the present disclosure, the transistor structure includes the semiconductor stack having the depletion region, the gate structure covering the depletion region, and the conductive element in the depletion region. The top surface of the metal layer in the conductive element directly contacts the bottom surface of the gate structure so that the vertical projection of the gate structure at least partially overlap with the metal layer. As a result, the conductive path in the semiconductor stack would pass through the metal layer in the depletion region, leading to the reduced resistivity of the conductive path. Therefore, the conductive element of the present disclosure may increase the current intensity of the transistor structure and improve the device performance.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A transistor structure, comprising:
a semiconductor stack, comprising:
a drift layer above a substrate, wherein the drift layer has a first conductive type;
a first doping region in the drift layer, wherein the first doping region has a second conductive type; and
a depletion region in the drift layer adjacent to the first doping region;
a gate structure on the semiconductor stack, wherein the gate structure covers the depletion region; and
a conductive element in the depletion region, wherein the conductive element comprises a metal layer, and a top surface of the metal layer directly contacts a bottom surface of the gate structure.

2. The transistor structure of claim 1, wherein a smallest distance between the conductive element and the first doping region is in a range of 0.4 μm to 0.6 μm.

3. The transistor structure of claim 1, wherein the gate structure comprises gate portions, a width of a gap between the gate portions in a first direction is smaller than a width of the top surface of the metal layer in the first direction.

4. The transistor structure of claim 1, wherein a depth of the conductive element from a top surface of the semiconductor stack is in a range of 1.6 μm to 2.4 μm.

5. The transistor structure of claim 1, wherein the top surface of the metal layer comprises a first portion directly contacting the gate structure and a second portion not contacting the gate structure, and the second portion is lower than the bottom surface of the gate structure.

6. The transistor structure of claim 1, wherein the conductive element further comprises a doping layer surrounding the metal layer, the doping layer has the first conductive type, and a doping concentration of the doping layer is higher than that of the drift layer.

7. The transistor structure of claim 6, wherein a thickness of the doping layer is in a range of 0.2 μm to 0.3 μm.

8. The transistor structure of claim 6, wherein the doping concentration of the doping layer is in a range of 1×10¹⁸ atoms/cm³ to 1×10²⁰ atoms/cm³.

9. The transistor structure of claim 1, further comprising:
a source contact above the semiconductor stack adjacent to the gate structure; and
a drain contact below the semiconductor stack, wherein an entire projection of the conductive element onto the drain contact overlaps the drain contact.

10. The transistor structure of claim 1, further comprising:
a second doping region in the first doping region, wherein the second doping region has the first conductive type, and a doping concentration of the second doping region is higher than that of the drift layer; and
a third doping region in the first doping region adjacent to the second doping region, wherein the third doping region has the second conductive type, and a doping concentration of the third doping region is higher than that of the first doping region.

11. A method of forming a transistor structure, comprising:
providing a semiconductor stack, wherein the semiconductor stack comprising:
a drift layer having a first conductive type above a substrate;
a first doping region having a second conductive type in the drift layer; and
a depletion region in the drift layer adjacent to the first doping region;
forming a gate structure above the semiconductor stack, wherein the gate structure covers the depletion region;
performing a first etching process to form a trench in the depletion region of the semiconductor stack; and
filling the trench with a metal layer to form a conductive element, wherein a top surface of the metal layer directly contacts a bottom surface of the gate structure.

12. The method of claim 11, wherein the first etching process is performed after forming the gate structure, the first etching process etches the gate structure to form an opening above the trench, and a width of the opening is smaller than that of the trench.

13. The method of claim 11, further comprising:
performing a second etching process after filling the trench with the metal layer to etch a portion of the top surface of the metal layer to a position lower than the bottom surface of the gate structure.

14. The method of claim 11, wherein the gate structure is formed after performing the first etching process, the bottom surface of the gate structure directly contacts entire of the top surface of the metal layer.

15. The method of claim 11, further comprising:
performing an ion implanting process on the drift layer before performing the first etching process to form a doping layer in the depletion region; and
performing the first etching process to form the trench in the doping layer of the depletion region.

16. The method of claim 15, wherein a depth of the doping layer from a top surface of the semiconductor stack is in a range of 1.6 μm to 2.4 μm.

17. The method of claim 11, further comprising:
performing an ion implanting process on the drift layer after performing the first etching process to form a doping layer along the trench, wherein a thickness of the doping layer is in a range of 0.2 μm to 0.3 μm.

18. The method of claim 17, wherein a smallest distance between the doping layer and the first doping region is in a range of 0.4 μm to 0.6 μm.

19. The method of claim 17, wherein performing the ion implanting process comprises doping the drift layer by using a dopant with the first conductive type, and a doping concentration of the ion implanting process is in a range of 1×10¹⁸ atoms/cm³ to 1×10²⁰ atoms/cm³.

20. The method of claim 17, further comprising:
performing an annealing process with an annealing temperature between 1400° C. and 1800° C. after performing the ion implanting process.
